(19) United States
(12) Patent Application Publication
(10) Pub. No.: US 2012/0139097 A1
(43) Pub. Date: Jun. 7, 2012

(54) SEMICONDUCTOR PACKAGE AND METHOD OF MANUFACTURING THE SAME

(76) Inventors: JEONGGI JIN, Osan-si (KR); Yunhyeok Im, Yongin-si (KR); Chungsun Lee, Gunpo-si (KR); Jung-Hwan Kim, Bucheon-si (KR); Tae-Hong Min, Gumi-si (KR)

(21) Appl. No.: 13/243,806

(22) Filed: Sep. 23, 2011

(30) Foreign Application Priority Data
Dec. 2, 2010 (KR) 10-2010-0122280

(51) Int. Cl. H01L 23/42; H01L 23/02

(52) U.S. Cl. 257/712; 257/678; 257/723; 257/E23.087; 257/E23.18

(57) ABSTRACT

Provided are a semiconductor package and a method of manufacturing the semiconductor package. The semiconductor package may include a circuit substrate, a semiconductor chip mounted on the circuit substrate, a chip package interaction disposed between the circuit substrate and the semiconductor chip, a first molding portion covering part of the semiconductor chip and part of the chip package interaction, a second molding portion formed on the first molding portion, and an adhesion portion adhering the first and second molding portions to each other, the adhesion portion being disposed between the first and second molding portions.

### CROSS-REFERENCE TO RELATED APPLICATION

This U.S. non-provisional patent application claims priority under 35 U.S.C. §119 to Korean Patent Application No. 10-2010-0122280, filed on Dec. 2, 2010, the entire contents of which are hereby incorporated by reference.

### BACKGROUND

The present inventive concept herein relates to semiconductor package and method of manufacturing the same, and more particularly, to a semiconductor package including a wafer level package and a method of manufacturing the same.

In a wafer level package, after forming a first molding portion protecting a chip package interaction and a semiconductor chip, a second molding portion protecting the chip package interaction, the semiconductor chip and a circuit substrate is formed. Adhesive strength between the first molding portion and the second molding portion may be relatively weak, and detachment of the molding portions may occur.

### SUMMARY

Embodiments of the inventive concept provide a semiconductor package. The semiconductor package may include a circuit substrate, a semiconductor chip mounted on the circuit substrate, a chip package interaction disposed between the circuit substrate and the semiconductor chip, a first molding portion covering part of the semiconductor chip and part of the chip package interaction, a second molding portion formed on the first molding portion, and an adhesion portion adhering the first and second molding portions to each other, the adhesion portion being disposed between the first and second molding portions.

Embodiments of the inventive concept also provide a semiconductor package. The semiconductor package may include a substrate, a semiconductor chip mounted on the substrate, a molding structure covering the semiconductor chip and the substrate. The molding structure comprises a first part adjacent to the semiconductor chip, a second part surrounding the first part, and an adhesion portion disposed between the first part and the second part.

Embodiments of the inventive concept also provide a method of manufacturing a semiconductor package. The method may include mounting a semiconductor chip on a chip package interaction so that a first side of the semiconductor chip faces a first side of the chip package interaction, forming a first molding portion covering a portion of the first side of the chip package interaction and a portion of sides of the semiconductor chip perpendicular to the first side of the semiconductor chip, mounting the chip package interaction on a circuit substrate, forming an adhesion portion along a surface profile of the semiconductor chip, the chip package interaction, the first molding portion and the circuit substrate, and forming a second molding portion on the adhesion portion to cover a portion of the first molding portion and a portion of the circuit substrate.

Embodiments of the inventive concept also provide a semiconductor package, comprising a circuit substrate, a chip package interaction on the circuit substrate, a plurality of semiconductor chips on the chip package interaction, a first molding portion on lateral sides of the semiconductor chips, an adhesion portion on the first molding portion and extending along lateral sides of the chip package interaction to the circuit substrate, and onto a top surface of the circuit substrate, and a second molding portion on the adhesion portion extending along lateral sides of the chip package interaction to the circuit substrate.

The adhesion portion may also extend on top of the semiconductor chips.

The plurality of semiconductor may be positioned next to each other in a horizontal direction or vertically stacked on the chip package interaction.

### BRIEF DESCRIPTION OF THE FIGURES

The foregoing and other features of the inventive concept will be apparent from the more particular description of embodiments of the inventive concept, as illustrated in the accompanying drawings in which like reference characters may refer to the same or similar parts throughout the different views. The drawings are not necessarily to scale, emphasis instead being placed upon illustrating the principles of the embodiments of the inventive concept. In the drawings, the thickness of layers and regions may be exaggerated for clarity.

FIG. 1 is a cross sectional view of a semiconductor module in accordance with embodiments of the inventive concept.

FIGS. 2A and 2B are enlarged cross sectional views of through silicon vias in a chip package interaction in a semiconductor module, in accordance with embodiments of the inventive concept.

FIGS. 3A and 3B are top plan views of a semiconductor package for explaining a structure of first molding portions in accordance with embodiments of the inventive concept.

FIGS. 4A and 4B are cross sectional views of a semiconductor package for explaining structures of second molding portions in accordance with embodiments of the inventive concept.

FIGS. 5A through 5C are enlarged cross sectional views of part of a semiconductor module for explaining an adhesion portion of a semiconductor package in accordance with embodiments of the inventive concept.

FIG. 6 is a cross sectional view of a semiconductor package for a semiconductor module in accordance with another embodiment of the inventive concept.

FIG. 7 is a cross sectional view of a semiconductor package for a semiconductor module in accordance with another embodiment of the inventive concept.

FIG. 8 is a cross sectional view of a semiconductor package for a semiconductor module in accordance with another embodiment of the inventive concept.

FIGS. 9A through 9M are cross sectional views for explaining a method of manufacturing a semiconductor module in accordance with embodiments of the inventive concept.

FIG. 10A is a block diagram illustrating a memory card including a semiconductor module in accordance with embodiments of the inventive concept.

FIG. 10B is a block diagram illustrating an information processing system to which a memory device in accordance with embodiments of the inventive concept is applied.

FIG. 10C is a perspective view illustrating a cell phone to which a semiconductor module in accordance with embodiments of the inventive concept is applied.

### DETAILED DESCRIPTION OF THE EMBODIMENTS

Exemplary embodiments of the inventive concept will be described below in more detail with reference to the accompanying drawings. The embodiments of the inventive concept may, however, be embodied in different forms and should not be constructed as limited to the embodiments set forth herein. Like numbers may refer to like elements throughout.

In the drawings, the thickness of layers and regions may be exaggerated for clarity. It will also be understood that when an element such as a layer, region or substrate is referred to as being “on” or “onto” another element, it may lie directly on the other element or intervening elements or layers may also be present.

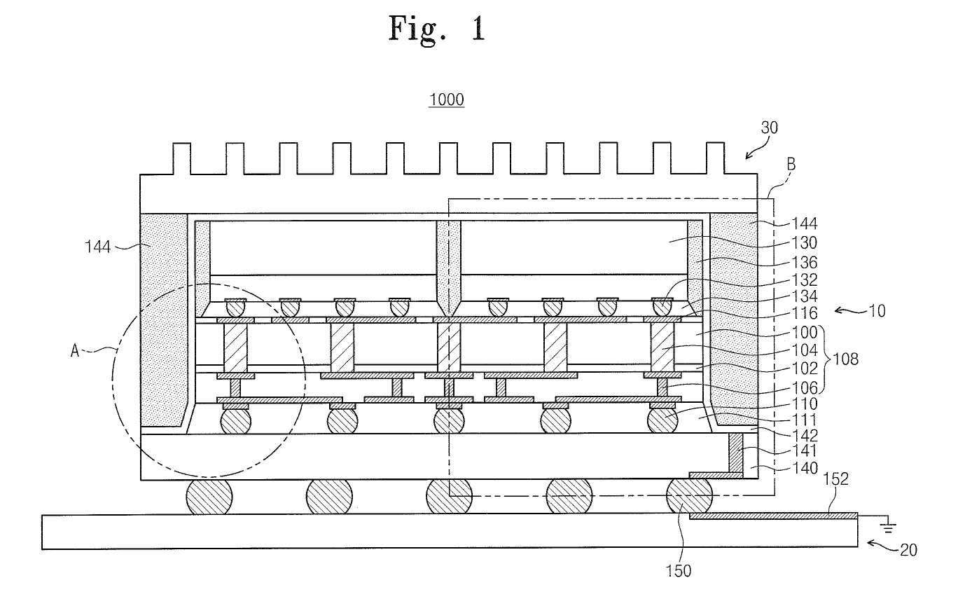

FIG. 1 is a cross sectional view of a semiconductor module in accordance with embodiments of the inventive concept.

Referring to FIG. 1, a semiconductor module 1000 includes a module substrate 20 and a semiconductor package 10.

The module substrate 20 is a substrate, for example, a mother board, in which a plurality of process devices are connected to one another. The module substrate 20 includes a circuit 152 to which a ground electric potential is applied.

The module substrate 20 is electrically connected to the semiconductor package 10. According to embodiments of the inventive concept, the semiconductor package 10 is electrically connected to one side of the module substrate 20 by first connection patterns 150. The first connection patterns 150 are, for example, solder balls.

Since the semiconductor package 10 is mounted on the module substrate 20, the module substrate 20, in accordance with an embodiment of the inventive concept, has a size that is larger than the semiconductor package 10.

The semiconductor package 10 includes a circuit substrate 140, a chip package interaction (CPI) 108, a semiconductor chip 130, a first molding portion 136, a second molding portion 144 and an adhesion portion 142. Referring to FIG. 1, the chip package interaction 108 and the semiconductor chip 130 are sequentially stacked on the circuit substrate 140.

The circuit substrate 140 may be, for example, a printed circuit board (PCB). The circuit substrate 140 includes a first side and a second side facing the first side. The second side of the circuit substrate 140 is disposed to face the module substrate 20. The circuit substrate 140 includes a circuit 141 connected to the circuit 152 to which a ground electric potential is applied.

As described above, the first connection patterns 150 are disposed between the circuit substrate 140 and the module substrate 20. One side of the circuit substrate 140 is spaced apart from the chip package interaction 108 while facing the chip package interaction 108.

The chip package interaction 108 includes a semiconductor substrate 100 and an interlayer insulating film 102. The semiconductor substrate 100 includes one side (back side) facing the semiconductor chip 130 and another side (active side) on which an integrated circuit (not illustrated) is disposed. The integrated circuit includes at least one of a random access memory (RAM), a nonvolatile memory, a memory control circuit, an application processor circuit, a power supplier circuit, a mode and a radio frequency circuit. The integrated circuit is electrically connected to pads 116 and a through silicon via (TSV) 104 through an interconnection pattern 106.

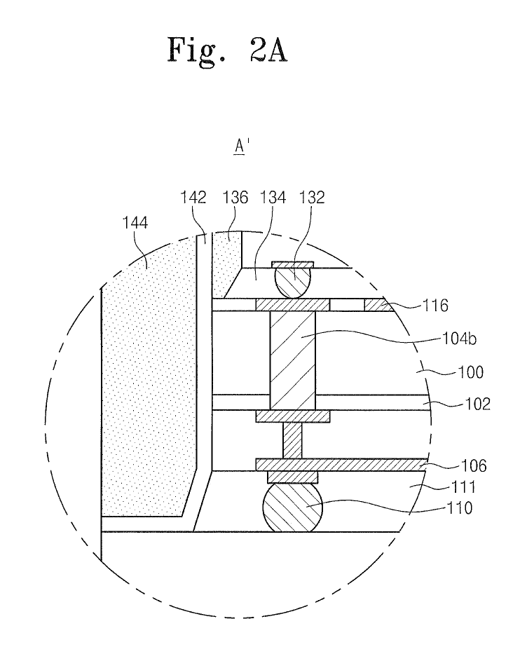

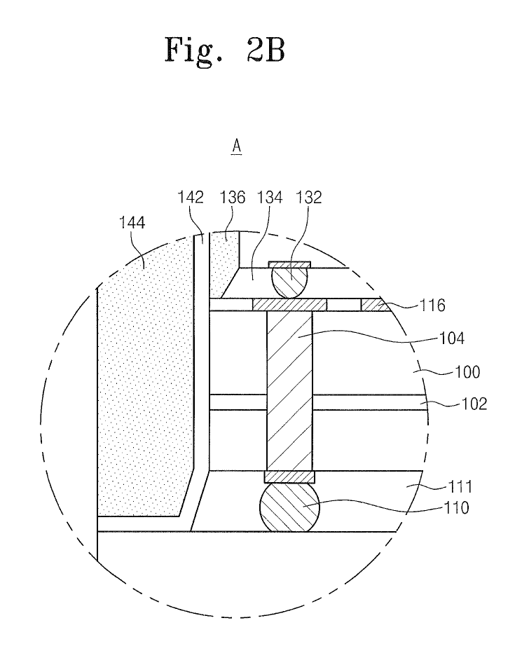

The chip package interaction 108 includes the through silicon via 104. The through silicon via 104 may have various shapes. FIGS. 1, 2A and 2B are cross sectional views for explaining shapes of through silicon vias 104 and 104b in the chip package interaction 108 in accordance with embodiments of the inventive concept. FIG. 2A is an enlarged views of “A” of FIG. 1, and FIG. 2B is a variation A′ of A of FIG. 1.

Referring to “A” of FIG. 1, the through silicon via 104 is a middle via type. The through silicon via 104 is formed during a formation of the integrated circuit and the interconnection pattern 106. The through silicon via 104 penetrates the semiconductor substrate 100 and a part of the interlayer insulating film 102. The through silicon via 104 is electrically connected to the pad 116 and to the integrated circuit through the interconnection pattern 106.

Referring to FIG. 2A, the through silicon via 104 is a first via type. Since the through silicon via 104 is formed before the integrated circuit and the interconnection pattern 106 are formed, the through silicon via 104 penetrate the semiconductor substrate 100 but does not penetrate the interlayer insulating film 102. The through silicon via 104 is electrically connected to the integrated circuit through the interconnection pattern 106 and to the pad 116.

Referring to FIG. 2B, the through silicon via 104b is a last via type. The through silicon via 104b is formed after the integrated circuit and the interconnection pattern 106 are formed. The through silicon via 104b penetrates the semiconductor substrate 100 and the interlayer insulating film 102. The through silicon via 104b is electrically and directly connected to the pad 116 or is electrically connected to the pad 116 through a redistributed interconnection.

A first under fill 111 covering the second connection patterns 110 is disposed in a space between the circuit substrate 140 and the chip package interaction 108. The second connection patterns 110 electrically connects the circuit substrate 140 and the chip package interaction 108. The second connection patterns 110 may have, for example, a ball shape. For example, the second connection patterns 110 may be a solder ball. The first under fill 111 protects the semiconductor package 10 from physical impact and chemical impact. The first under fill 111 includes, for example, an insulating material.

The semiconductor chip 130 is spaced apart from and faces the chip package interaction 108. Referring to FIG. 1, a side of the semiconductor chip 130 faces a side of the chip package interaction 108.

The semiconductor chip 130, in accordance with an embodiment of the inventive concept, has a size smaller than the chip package interaction 108. A plurality of semiconductor chips 130 may be disposed on the chip package interaction 108. According to an embodiment of the inventive concept, the semiconductor chips 130 disposed on the chip package interaction 108 are horizontally spaced apart from one another on one side of the chip package interaction 108. Although two semiconductor chips 130 are illustrated in FIG. 1 as an example, the quantity of the semiconductor chips 130 is not limited thereto.

The semiconductor chip 130 and the chip package interaction 108 are electrically connected to each other by third connection patterns 132. The third connection patterns 132 may have a ball shape. For instance, the third connection patterns 132 are solder balls. The third connection patterns 132, in accordance with an embodiment of the inventive concept, are smaller than the second connection patterns 110.

A second under fill 134 covering the third connection patterns 132 is disposed between the semiconductor chip 130 and the chip package interaction 108. The second under fill 134 protects the semiconductor package 10 from physical impact and chemical impact. The second under fill 134 includes, for example, an insulating material. The second under fill 134 may be formed of the same material as the first under fill 111.

The first molding portion 136 partly covers the semiconductor chip 130, the second under fill 134 and the chip package interaction 108. More specifically, the first molding portion 136 contacts lateral sides of the semiconductor chip 130 and the second under fill 134 and a part of a side of the chip package interaction 108 facing the semiconductor chip 130. In the case that there are a plurality of the semiconductor chips 130, the first molding portion 136 also fills a space between adjacent semiconductor chips 130. A height of the first molding portion 136, in accordance with an embodiment of the inventive concept, is the same as the sum of a height of the semiconductor chip 130 and a height of the third connection pattern 132. For example, a top surface of the first molding portion 136 is even with a side of the semiconductor chip 130. The first molding portion 136 may include, for example, an epoxy molding compound.

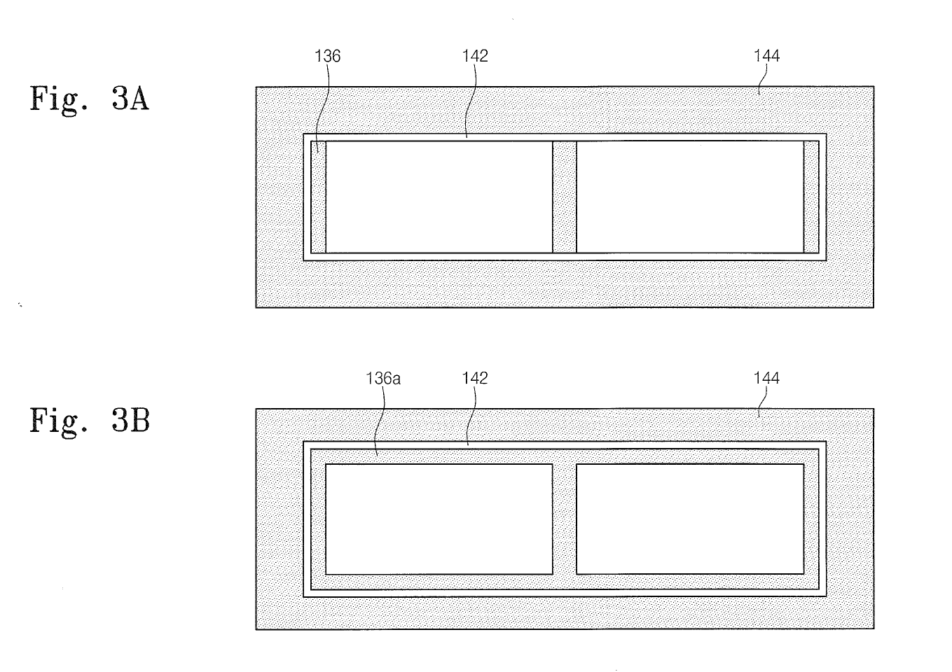

The first molding portion 136 may be disposed to surround the semiconductor chip 130 with various structures. FIGS. 3A and 3B are top plan views of a semiconductor package for explaining structures of first molding portions 136 and 136a of a semiconductor package 10 in accordance with embodiments of the inventive concept.

Referring to FIG. 3A, the first molding portion 136 contacts lateral sides of the semiconductor chip 130, that is, side surfaces of the semiconductor chip 130. More specifically, in accordance with an embodiment of the inventive concept, the semiconductor chips 130 have a rectangular structure having a long side and a short side when viewed from a top plan view. The first molding portion 136 contacts the short sides of the semiconductor chips 130.

Referring to FIG. 3B, the first molding portion 136a contact all four sides of the semiconductor chips 130.

The second molding portion 144 is disposed adjacent to the first molding portion 136 and is disposed to partly cover the chip package interaction 108, the first under fill 111 and the circuit substrate 140. The second molding portion 144 may include the same material as the first molding portion 136. Alternatively, the second molding portion 144 includes a different material from the first molding portion 136.

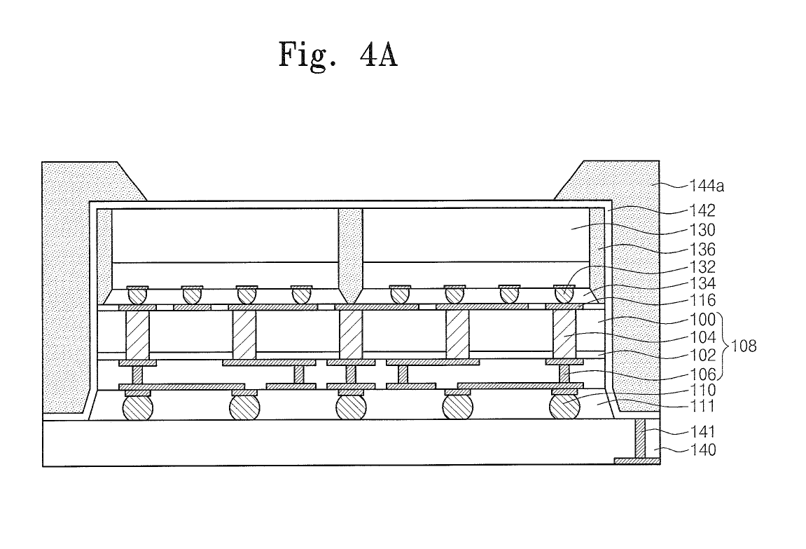

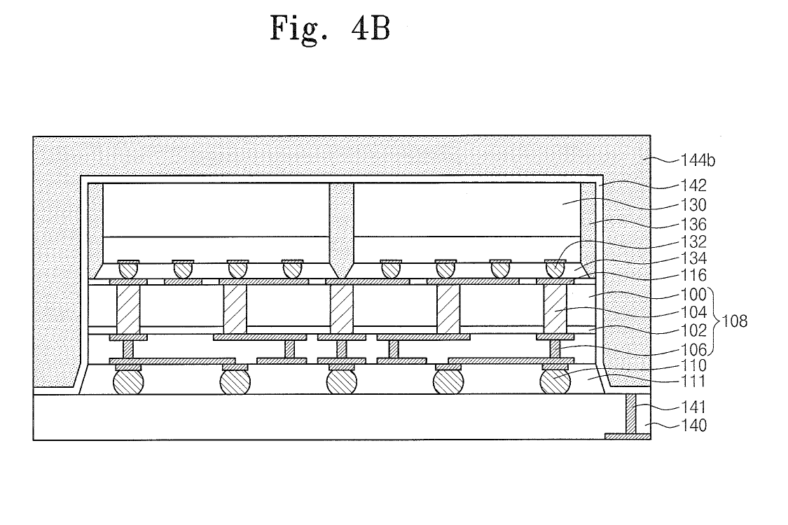

The second molding portion may have various shapes. FIGS. 1, 4A and 4B are cross sectional views illustrating structures of the second molding portion 144, 144a and 144b of a semiconductor module in accordance with embodiments of the inventive concept. Referring to FIG. 1, the second molding portion 144 is disposed along side surfaces of the first molding portion 136, side surfaces of the first under fill 111 and on top of the circuit substrate 140. A height of the second molding portion 144 is substantially the same as the sum of heights of the semiconductor chip 130, the third connection pattern 132, the chip package interaction 108 and the second connection pattern 110. For instance, a top surface of the second molding portion 144 may be even with a top surface of the first molding portion 136, or may extend a distance beyond the top surface of the first molding portion 136 equal or approximately equal to a thickness of the adhesion portion 142. Referring to FIG. 4A, the second molding portion 144a extends onto a top surface of the first molding portion 136, and onto a top surface of the semiconductor chip 130. According to an embodiment, the second molding portion extends onto the top surface of the first molding portion 136, but does not completely cover the top surface of the first molding portion 136, and does not extend onto the top surface of the semiconductor chip 130. Referring to FIG. 4B, the second molding portion 144b completely covers the top surface of the first molding portion 136 and of the semiconductor chip 130.

Shapes of the second molding portion 144, 144a and 144b are illustrated in the present embodiments by example and a shape of the second molding portion is not limited thereto.

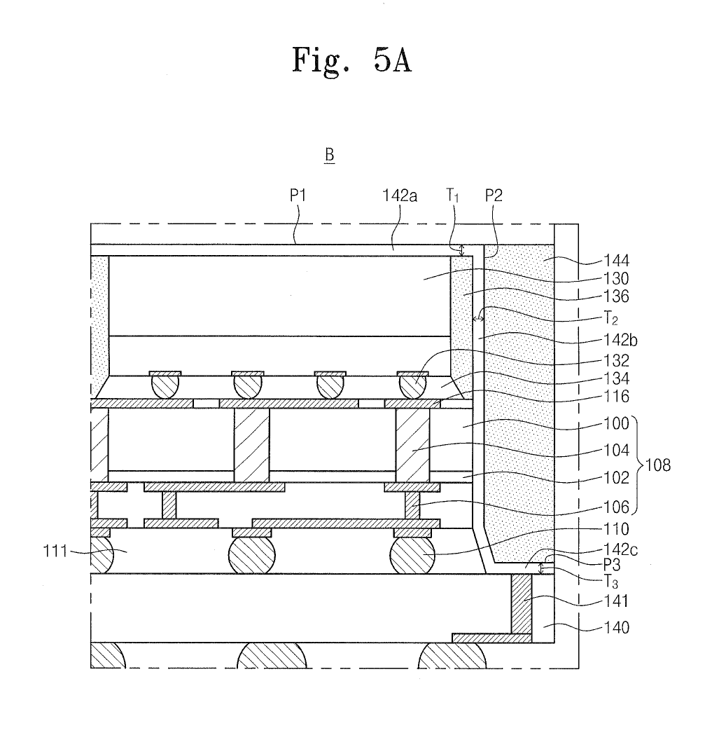

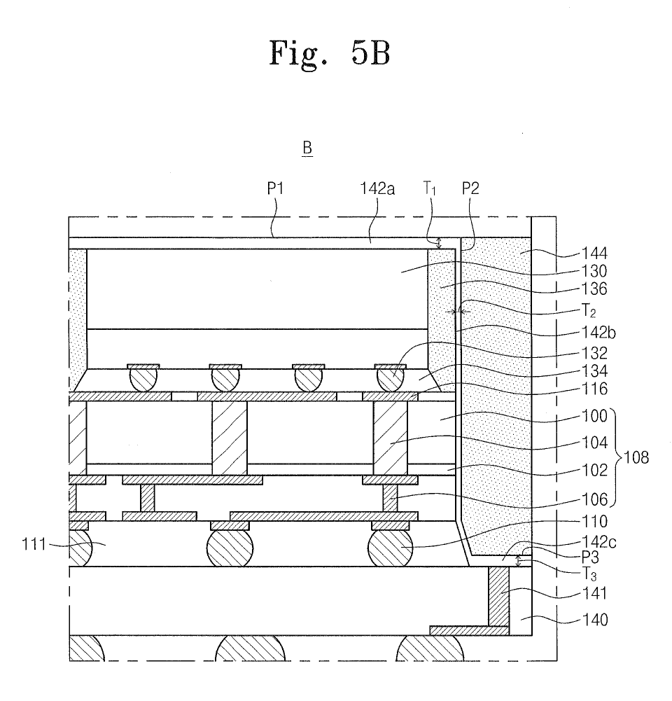

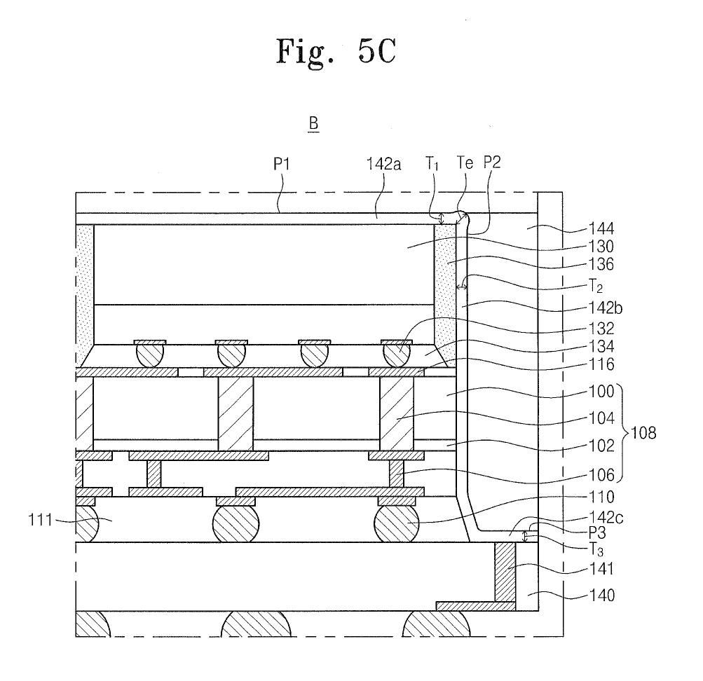

The adhesion portion 142 is disposed between the first and second molding portions 136 and 144 to improve an adhesive strength between the first and second molding portions 136 and 144. Referring to FIGS. 5A-5C, the adhesion portion 142 in accordance with embodiments of the inventive concept includes a first part P1, a second part P2 and a third part P3. The first part P1 extends along a top surface of the first molding portion 136 and along a surface of the semiconductor chip 130. The second part P2 extends along side surfaces of the first molding portion 136, the chip package interaction 108 and the first under fill 111 from both ends of the first part P1. The third part P3 extends along a surface of the circuit substrate 140 second parts P2 on opposite sides of the semiconductor package 10.

The first through third parts P1, P2 and P3 of the adhesion portion 142 may have various thicknesses. FIGS. 5A through 5C are cross sectional views for explaining the adhesion portion 142 of the semiconductor package 10 in accordance with embodiments of the inventive concept. FIGS. 5A through 5C are enlarged views of “B” of FIG. 1.

Referring to FIG. 5A, the first through third parts P1, P2 and P3 of the adhesion portion 142 have substantially the same thickness as each other (T1=T2=T3). Referring to FIG. 5B, the first and second parts P1 and P3 have a first thickness T1 and T3 equal or substantially equal to each other. The second part P2 has a second thickness T2 smaller than the first thickness T1 and T3. Referring to FIG. 5C, the first through third parts P1, P2 and P3 of the adhesion portion 142 a first thickness T1, T2 and T3 equal or substantially equal to each other and portions where the first part P1 meets the second part P2 at both ends of the first part P1 have a second thickness Te greater than the first thickness.

The adhesion portion 142 in accordance with embodiments of the inventive concept may include an insulating material such as epoxy resin, polyimide or a permanent photoresist. The adhesion portion 142 may further include thermal interface material (TIM), metal paste and nano-particles to improve thermal emission characteristics. Also, the adhesion portion 142 may include conductive material such as metal foil or shielding case material.

According to embodiments of the inventive concept, an end of the adhesion portion 142 is electrically connected to a circuit of the module substrate 20 to which a ground electric potential is applied. For example, an end of the adhesion portion 142 is electrically connected to the module substrate 20 through the circuit substrate 140. Alternatively, an end of the adhesion portion 142 is directly connected to a circuit of the module substrate 20.

Referring to FIG. 1, the semiconductor device further includes a heat sink 30. According to an embodiment, the heat sink 30 is disposed on a surface of the semiconductor chip 130, a top surface of the first molding portion 136 and a top surface of the second molding portion 144.

The adhesion portion 142 between the first and second molding portions 136 and 144 improves an adhesive strength between the first and second molding portions 136 and 144. Also, the adhesion portion 142 including a conductive material, is connected to a circuit of the module substrate to which a ground electric potential is applied. As a result, electromagnetic interference (EMI) and noise characteristics may be improved. Thermal emission characteristics of a semiconductor module may be improved by an adhesion portion to which thermal interface material (TIM), metal paste and nano-particles are added.

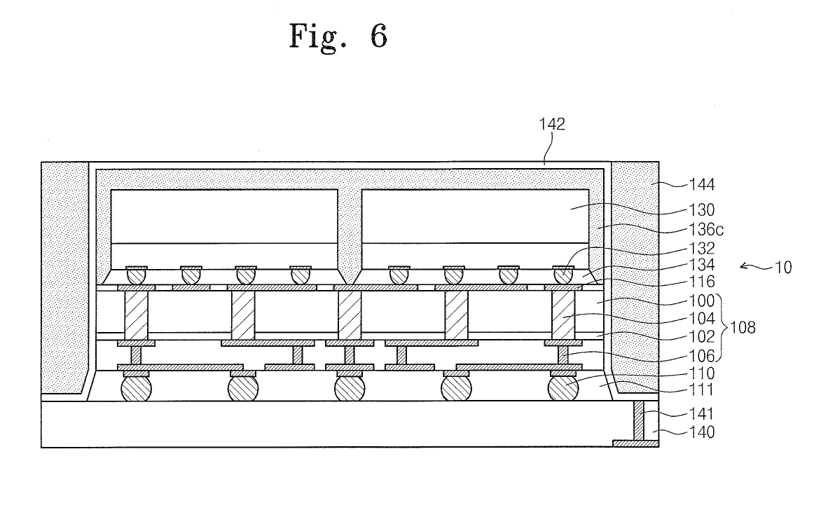

FIG. 6 is a cross sectional view of a semiconductor package of a semiconductor module in accordance with another embodiment of the inventive concept.

Referring to FIGS. 1 and 6, a semiconductor module 1000 includes a module substrate 20 and a semiconductor package 10. When comparing with FIG. 1, the first molding portion 136c in accordance with the present embodiment is disposed to completely cover an upper surface of the semiconductor chip 130. The semiconductor package 10 shown in FIG. 6 includes a circuit substrate 140, a chip package interaction (CPI) 108, a semiconductor chip 130, a first molding portion 136c, a second molding portion 144 and an adhesion portion 142.

The first module portion 136 contacts the upper surface of the semiconductor chip 130, side surfaces perpendicular to the upper surface of the semiconductor chip 130 and side surfaces of a second under fill 134. A height of the first molding portion 136c is greater than the sum of heights of the second under fill 134 and the semiconductor chip 130.

The second molding portion 144 is disposed adjacent to the first molding portion 136c and partly covers the chip package interaction 108, a first under fill 111 and the circuit substrate 140. The second molding portions 144a and 144b, as illustrated in FIGS. 4A and 4B, may have various shapes. In the present embodiments, although shapes of the second molding portions 144, 144a and 144b are illustrated, a shape of the second molding portion is not limited thereto.

The adhesion portion 142 is disposed between the first and second molding portions 136c and 144 to improve an adhesive strength between the first and second molding portions 136c and 144. The adhesion portion 142 in accordance with embodiments of the inventive concept may include a first part P1, a second part P2 and a third part P3. Referring to FIGS. 5A-5C, the first part P1 extends along a top surface of the first molding portion 136 and one side of the semiconductor chip 130. The second part P2 extends along side surfaces of the first molding portion 136, the chip package interaction 108 and the first under fill 111 from both ends of the first part P1. The third part P3 extends along one side of the circuit substrate 140 from the second parts P2 located on opposite sides of the semiconductor package 10.

The descriptions of constituent structures of a semiconductor module which are not described in detail in the present embodiment are the same or substantially the same as the descriptions of the semiconductor module illustrated with reference to FIGS. 1, 2A, 2B, 3A, 3B, 4A, 4B, 5A, 5B and 5C.

FIG. 7 is a cross sectional view of a semiconductor package for explaining a semiconductor module in accordance with another embodiment of the inventive concept.

Referring to FIGS. 1 and 7, a semiconductor module 1000 includes a module substrate 20 and a semiconductor package 10. The semiconductor package 10 includes a circuit substrate 140, a chip package interaction (CPI) 108, a semiconductor chip 130, a first molding portion 136, a second molding portion 144 and an adhesion portion 142.

The adhesion portion 142 is disposed between the first and second molding portions 136 and 144 to improve an adhesive strength between the first and second molding portions 136 and 144. The adhesion portion 142 in accordance with embodiments of the inventive concept may have a multilayer structure. Referring to FIG. 7, the adhesion portion 142 includes a first layer 142c and a second layer 142d. The first and second layers 142c and 142d include, for example, insulating material such as epoxy resin, polyimide or permanent photoresist and have an adhesive strength. The first layer 142c, in accordance with an embodiment of the inventive concept, further includes conductive material, such as metal foil or shielding case material. The first layer 142c of the adhesion portion 142 is connected to a circuit of the module substrate 20 to which a ground electric potential is applied and thereby electromagnetic interference (EMI) and a noise characteristics may be improved. The second layer 142d, in accordance with an embodiment of the inventive concept, further includes thermal interface material (TIM), metal paste and nano-particles to improve thermal emission characteristics.

The descriptions of constituent structures of a semiconductor module which are not described in detail in the present embodiment are the same or substantially the same as the descriptions of the semiconductor modules illustrated in FIGS. 1, 2A, 2B, 3A, 3B, 4A, 4B, 5A, 5B, 5C and 6.

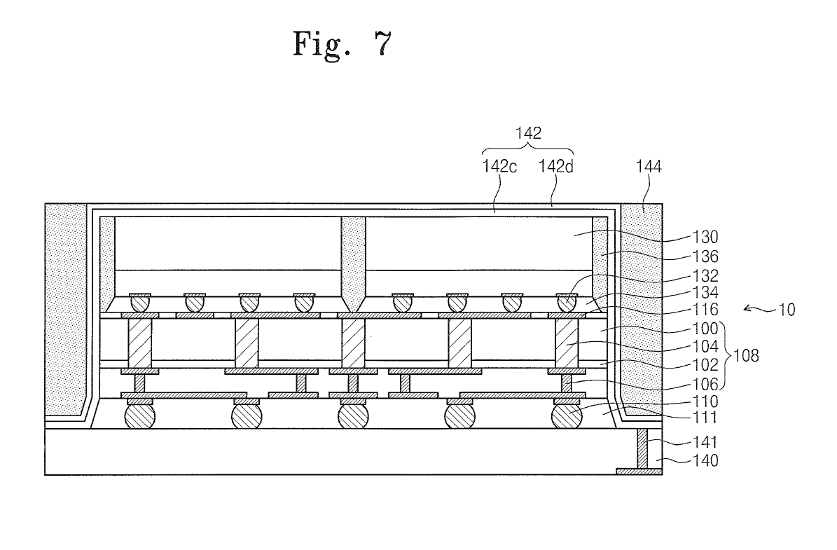

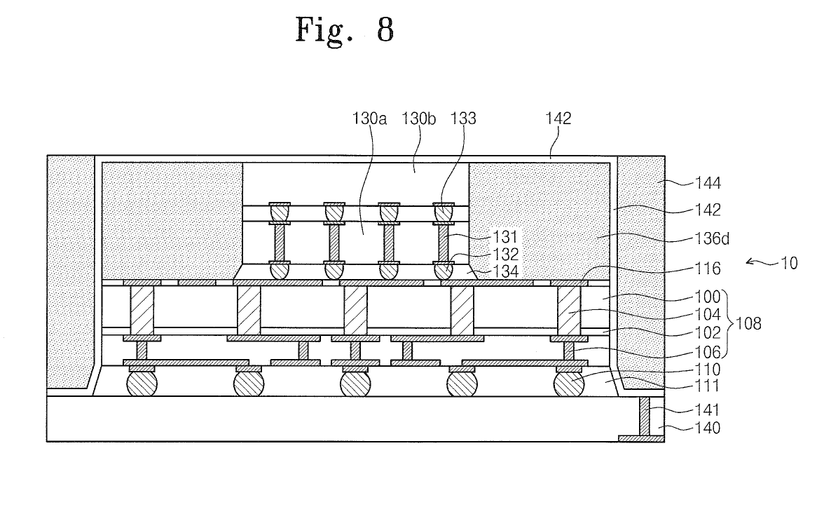

FIG. 8 is a cross sectional view of a semiconductor package for explaining a semiconductor module in accordance with another embodiment of the inventive concept.

Referring to FIGS. 1 and 8, a semiconductor module 1000 includes a module substrate 20 and a semiconductor package 10. Referring to FIG. 8, the semiconductor package 10 includes a circuit substrate 140, a chip package interaction (CPI) 108, semiconductor chips 130a and 130b, a first molding portion 136d, a second molding portion 144 and an adhesion portion 142.

According to embodiments of the inventive concept, two or more semiconductor chips may be stacked on one side of the chip package interaction 108. The semiconductor chips 130 are electrically connected to one another.

Although a structure in which two semiconductor chips 130a and 130b are stacked is described in the present embodiment as an example, the quantity of the semiconductor chips 130 is not limited thereto.

The semiconductor chips include a first semiconductor chip 130a disposed to be adjacent to the chip package interaction 108 and a second semiconductor chip 130b disposed on the first semiconductor chip 130a. The first and second semiconductor chips 130a and 130b are spaced apart from each other. The first and second semiconductor chips 130a and 130b are electrically connected to each other by fourth connection patterns 133. The first semiconductor chip 130a includes a through silicon via 131. The through silicon via 131 may be a first via type, a middle via type or a last via type.

The descriptions of constituent structures of a semiconductor module which are not described in detail in the present embodiment are the same or substantially the same as descriptions of semiconductor modules illustrated in FIGS. 1, 2A, 2B, 3A, 3B, 4A, 4B, 5A, 5B, 5C, 6 and 7.

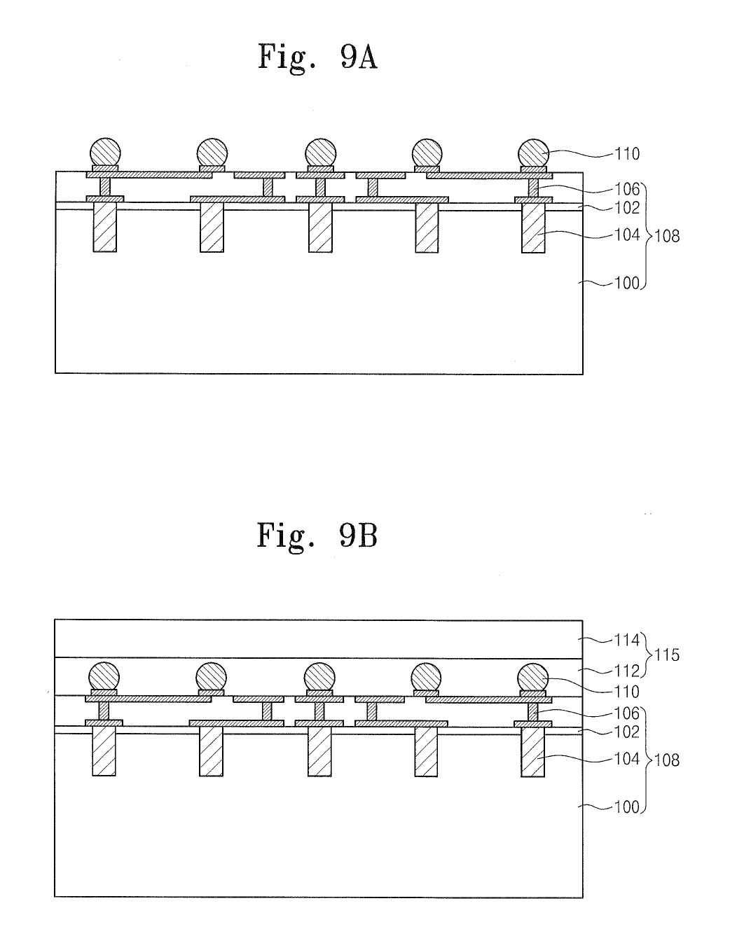

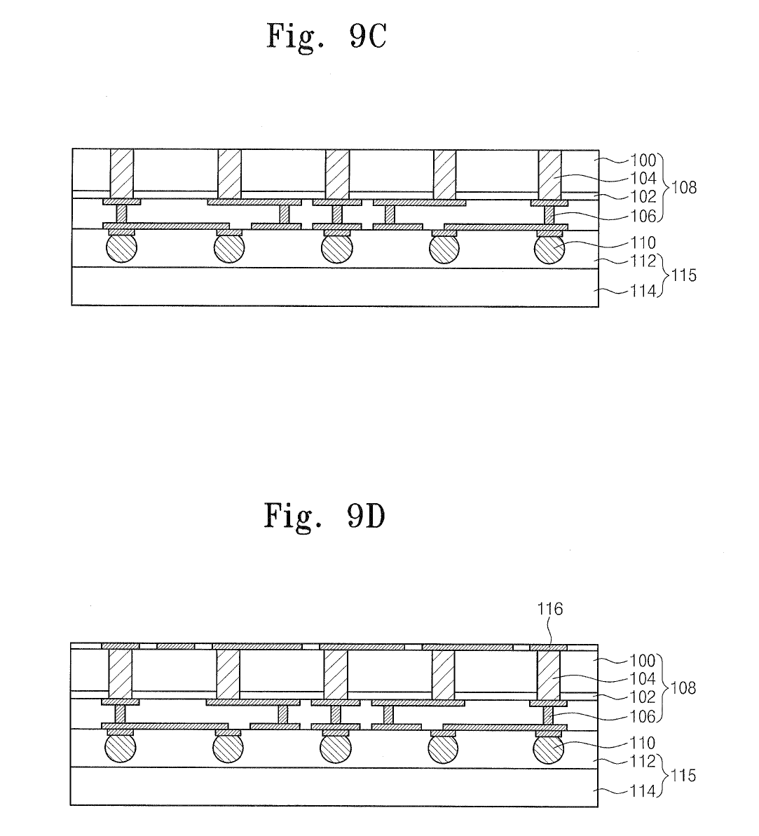

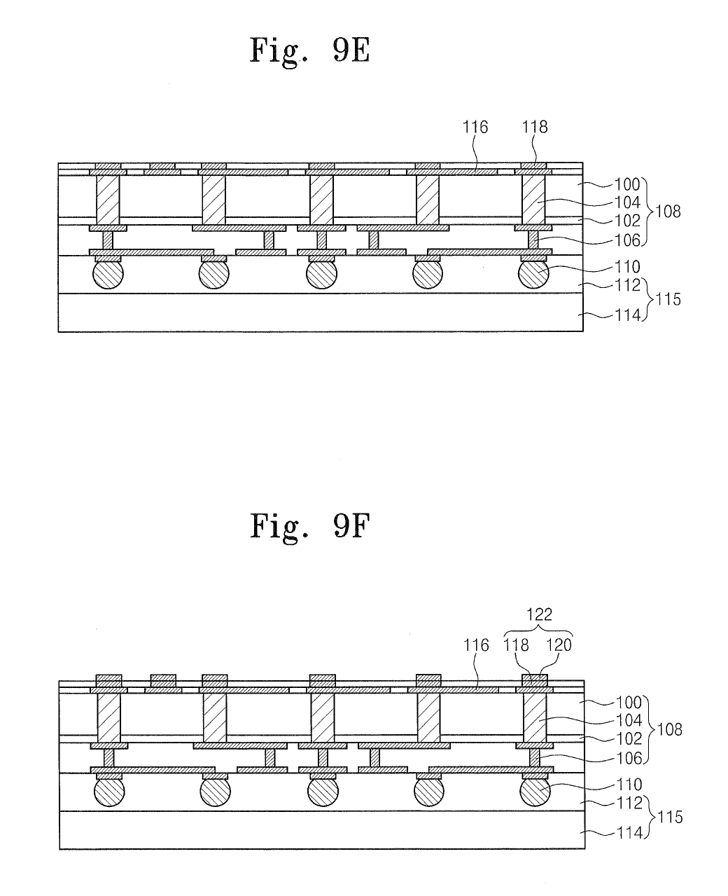

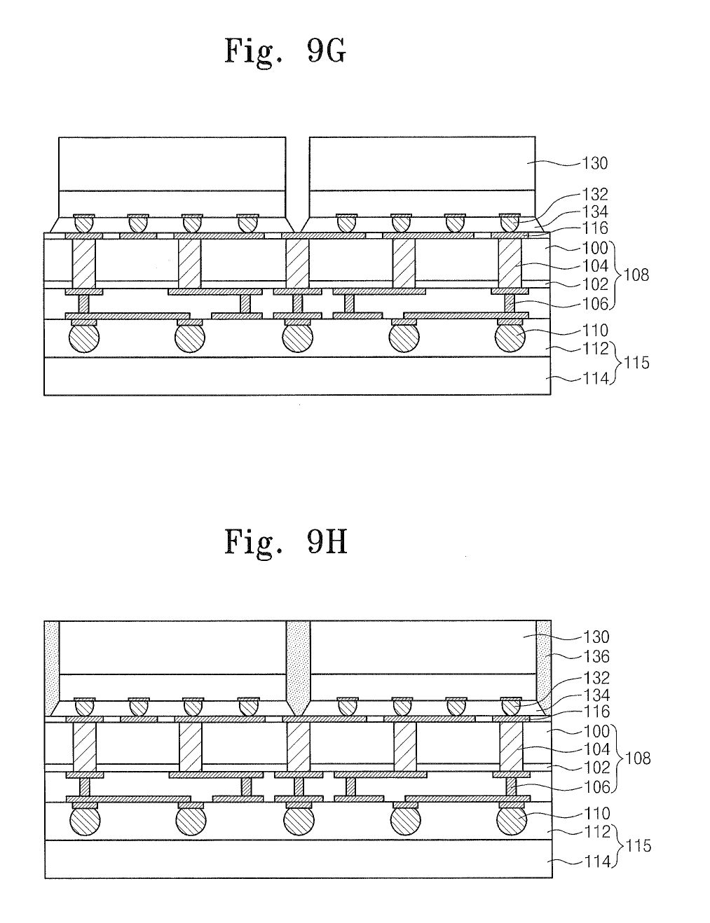

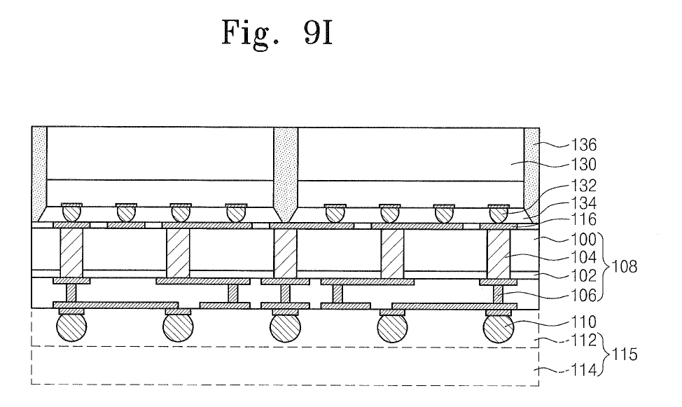

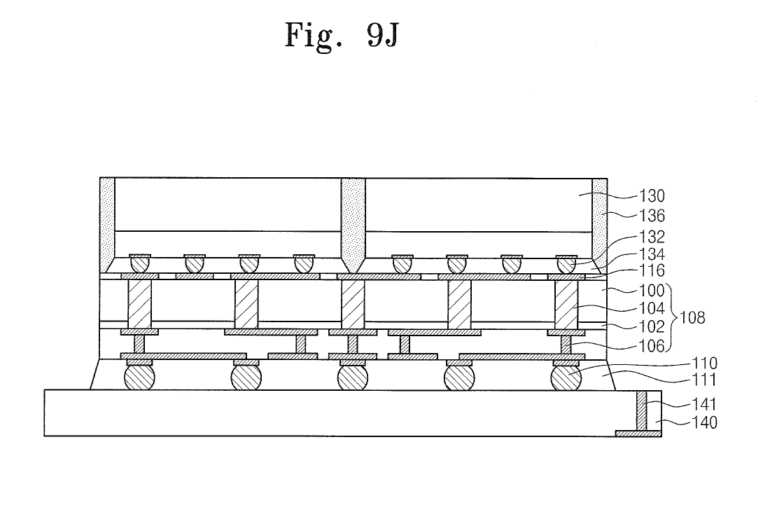

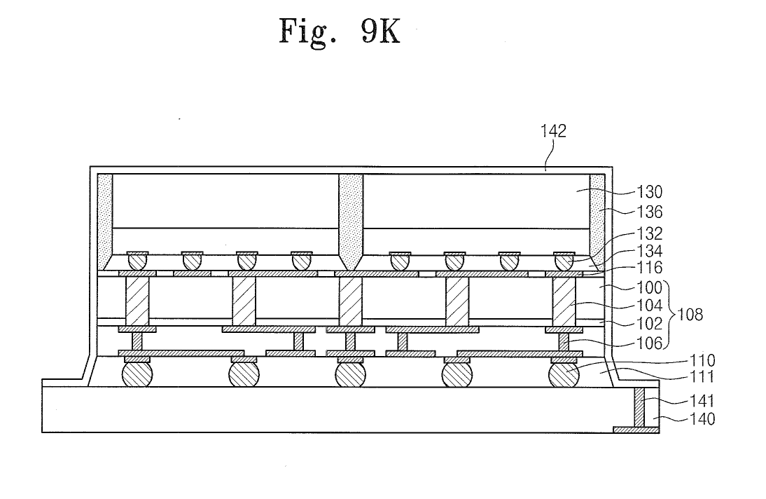

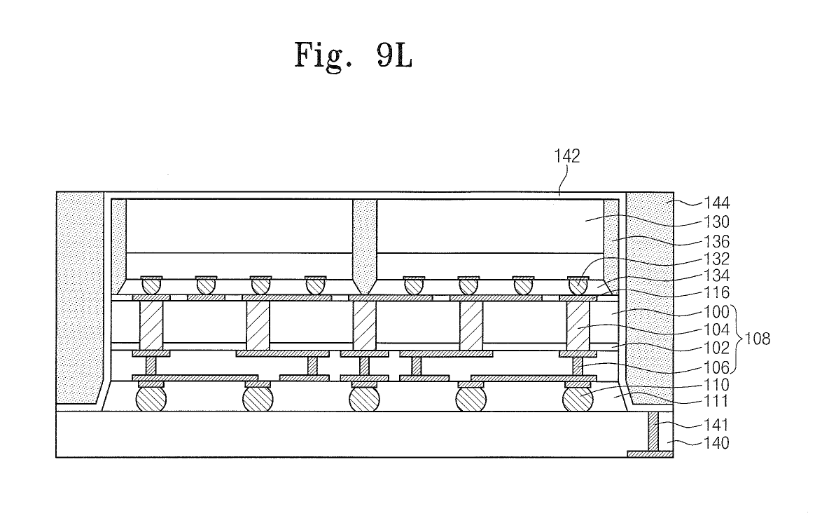

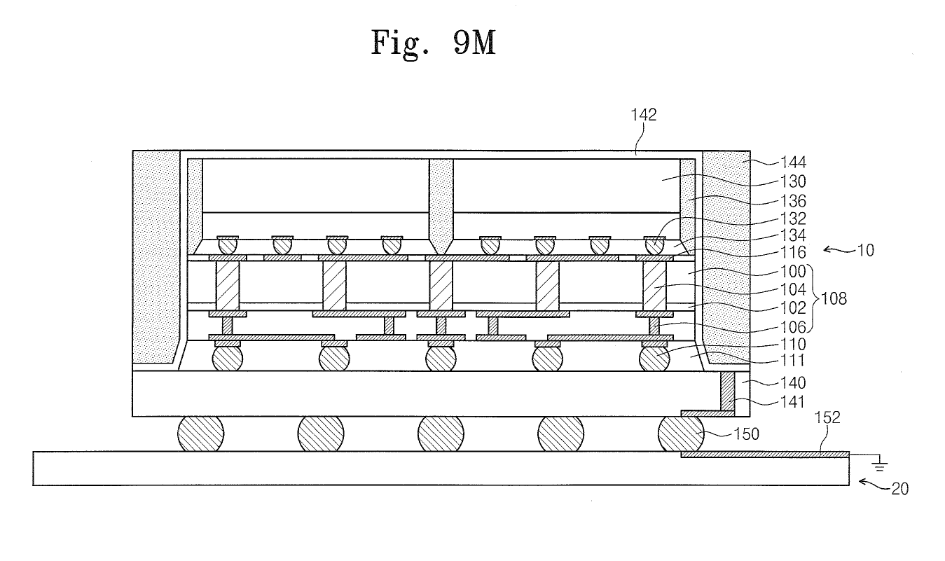

FIGS. 9A through 9M are cross sectional views for explaining a method of manufacturing a semiconductor module in accordance with embodiments of the inventive concept. Hereinafter, although the terms first through third, etc. may be used to describe particular elements, the use of these terms does not necessarily indicate an order in which the elements are formed.

Referring to FIG. 9A, a chip package interaction (CPI) 108 and second connection patterns 110 are formed.

A process of forming the chip package interaction 108 is described as follows. A through silicon via 104 is formed in a part of an interlayer insulating film 102 and a part of a semiconductor substrate 100. According to an embodiment, the through silicon via 104 is formed during formation of an integrated circuit and an interconnection circuit. According to another embodiment, the through silicon via 104 partly penetrating the semiconductor substrate 100 is formed, and then the integrated circuit and the interconnection circuit are formed. A through silicon via 104 formed by an embodiment may be a first via and may have the structure shown in FIG. 2A. According to another embodiment, after forming the integrated circuit and the interconnection circuit, the through silicon via 104b may be a last via and may have the structure shown in FIG. 2B. The interconnection circuit electrically connected to the through silicon vias 104, 104b may be formed on a side of the chip package interaction 108 where the second connection patterns 110 are formed.

In accordance with an embodiment of the inventive concept, the second connection patterns 110 electrically connected to the interconnection circuit are formed on the chip package interaction 108.

Referring to FIG. 9B, a protection structure 115 protecting the second connection patterns 110 is formed. The protection structure 115, in accordance with an embodiment of the inventive concept, has a multilayer structure. For instance, the protection structure 115 includes an adhesion layer 112 formed to cover the second connection patterns 110 and a protection layer structure 114 formed on the adhesion layer 112.

Referring to FIG. 9C, a back side of the semiconductor substrate 100 of the chip package interaction 108 is polished. The semiconductor substrate 100 is polished until a side of each of the through silicon vias 104 is exposed. Removal of the excess portions of the semiconductor substrate may be performed by, for example, an etch-back process, a back grinding process or a chemical mechanical polishing process.

Referring to FIG. 9D, pads 116 electrically connected to the through silicon vias 104 are formed on a back side of the polished semiconductor substrate 100.

Referring to FIGS. 9E and 9F, the pads 116 are redistributed.

A process of redistributing the pads 116 is described as follows. Micro pads 118 are formed on the pads 116. Redistributed line patterns 120 are formed on the micro pads 118 using electroless plating. According to embodiments of the inventive concept, the steps in FIGS. 9E and 9F may be omitted depending on design specifications. The redistributed structure 122 is omitted from FIG. 9G and subsequent figures.

Referring to FIG. 9G, semiconductor chip(s) 130 are electrically connected to the chip package interaction 108.

More specifically, the semiconductor chips 130 are electrically connected to the chip package interaction 108 by third connection patterns 132. According to an embodiment, after the third connection patterns 132 are formed on the pads 116, the semiconductor chips 130 are electrically connected to the third connection patterns 132. According to another embodiment, after the third connection patterns 132 are formed on the semiconductor chips 130, the third connection patterns 132 are electrically connected to the pads 116. A second under fill 134 covering the third connection patterns 132 is formed in a space between the semiconductor chips 130 and the chip package interaction 108.

According to embodiments, one or more semiconductor chips 130 may be disposed on the chip package interaction, and may be disposed to be horizontally spaced apart from one another on the chip package interaction 108, or, as illustrated in FIG. 8, to be vertically stacked on the chip package interaction (CPI) 108.

Referring to FIG. 9H, a first molding portion 136 covering the chip package interaction 108 on which the semiconductor chips 130 are mounted is formed.

According to an embodiment, the first molding portion 136 is formed to cover lateral side surfaces of the semiconductor chip 130. A top surface of the first molding portion 136 is even with a top surface of the semiconductor chip 130. According to another embodiment, as illustrated in FIG. 6, the first molding portion 136c covers a top surface of the semiconductor chips 130.

Referring to FIG. 9I, the protection structure 115 covering the second connection patterns 110 is removed from the chip package interaction 108 to expose the second connection patterns 110.

Referring to FIG. 9J, the chip package interaction 108 is electrically connected to the circuit substrate 140. More specifically, the circuit substrate 140 and the chip package interaction 108 are electrically connected to each other by electrically connecting the second connection patterns 110 with the circuit substrate 140.

A first under fill 111 covering the second connection patterns 110 is formed in a space between the chip package interaction 108 and the circuit substrate 140.

Referring to FIG. 9K, an adhesion portion 142 is conformally and continuously formed on a top surface of the semiconductor chip 130, side surfaces of the first molding portion 136, side surfaces of the chip package interaction 108 and a top surface of the circuit substrate 140.

Methods of forming the adhesion portion 142 may vary. According to an embodiment, the adhesion portion 142 is formed by coating an adhesion material using a spin coating method. According to another embodiment, the adhesion portion 142 is formed by coating an adhesion material using a spray method. According to another embodiment, the adhesion portion 142 is formed by taping an adhesion material.

Thicknesses of parts of the adhesion portion 142 may be equal to or different from each other depending on a formation method or a formation condition. For example, refer to FIGS. 5A, 5B and 5C and the corresponding discussion for descriptions regarding the thicknesses of parts of the adhesion portion 142.

The adhesion portion 142 includes, for example, an insulating material such as epoxy resin, polyimide or permanent photoresist. The adhesion portion 142 may further include thermal interface material (TIM), metal paste and nano-particles to improve thermal emission characteristics. Also, the adhesion portion 142 may include conductive material such as metal foil or shielding case material.

Referring, for example to FIGS. 1, 6 and 8, a profile of the adhesion portion 142 may be changed depending on a structure of the first molding portion 136 and a structure of the semiconductor chip 130.

According to another embodiment, as illustrated in FIG. 7, the adhesion portion 142 is formed to have a multilayer structure. More specifically, a first layer 142c to which a conductive material, such as metal foil or shielding case material, is added to an insulating material, such as epoxy resin, polyimide or permanent photoresist, is formed. A second layer 142d to which thermal interface material (TIM), metal paste and nano-particles are added to an insulating material, such as epoxy resin, polyimide or permanent photoresist, is formed on the first layer 142d. As a result, the adhesion portion 142 having a multilayer structure in which the first and second layers 142c and 142d are stacked is formed.

Referring to FIG. 9L, a second molding portion 144 is formed on the adhesion portion 142.

According to an embodiment of the inventive concept, the second molding portion 144 is formed on a side surface of the first molding portion 136, a side surface of the chip package interaction 108 and a top surface of the circuit substrate 140. A top surface of the second molding portion 144 may be even with or higher than a top surface of the semiconductor chip 130 by a thickness of the adhesion portion 142. According to another embodiment of the inventive concept, as illustrated in FIG. 4A, the second molding portion 144a is formed to partly cover a top surface of the first molding portion 136 and a top surface of the semiconductor chip 130. According to another embodiment of the inventive concept, as illustrated in FIG. 4B, the second molding portion 144b may be formed to completely cover top surfaces of the first molding portion 136 and the semiconductor chip 130. However, a structure or a shape of the second molding portion 144, 144a, 144b is not limited thereto.

A semiconductor package 10 including the semiconductor chip 130, the chip package interaction 108, the circuit substrate 140, the first molding portion 136, the second molding portion 144 and the adhesion portion 142 is formed.

Referring to 9M, the semiconductor package 10 is mounted on a module substrate 20.

The semiconductor package 10 and the module substrate 20 are connected by first connection patterns 150.

According to embodiments of the inventive concept, one end of the adhesion portion 142 is electrically connected to a circuit 152 to which a ground electric potential of the module substrate 20 is applied. According to an embodiment, one end of the adhesion portion 142 is electrically connected to the module substrate 20 through a circuit 141 of the circuit substrate 140. According to another embodiment, one end of the adhesion portion 142 is directly connected to the circuit 152 of the module substrate 20.

Referring back to FIG. 1, a heat sink 30 is formed on the semiconductor chip 130, the first molding portion 136 and the second molding portion 144. According to an embodiment, the heat sink 30, after completing the semiconductor package 10, is disposed on the semiconductor package before mounting the semiconductor package 10 on the module substrate 20. According to another embodiment, the heat sink 30 is disposed on the semiconductor package after mounting the semiconductor package 10 on the module substrate 20.

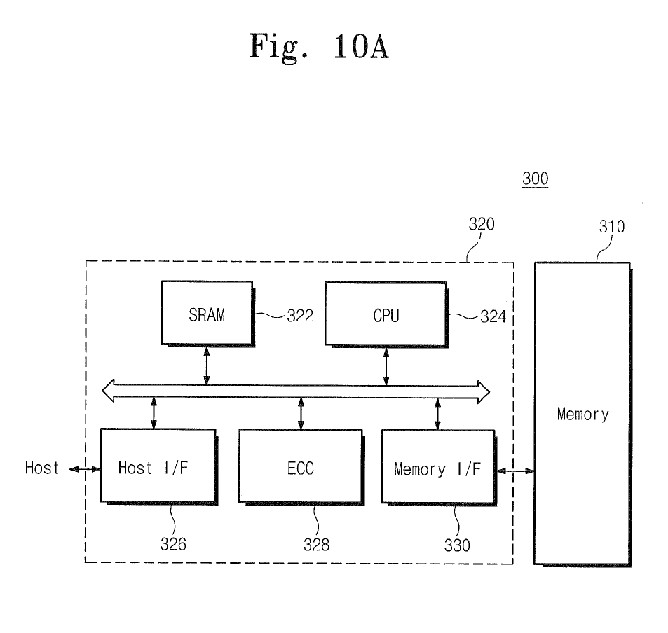

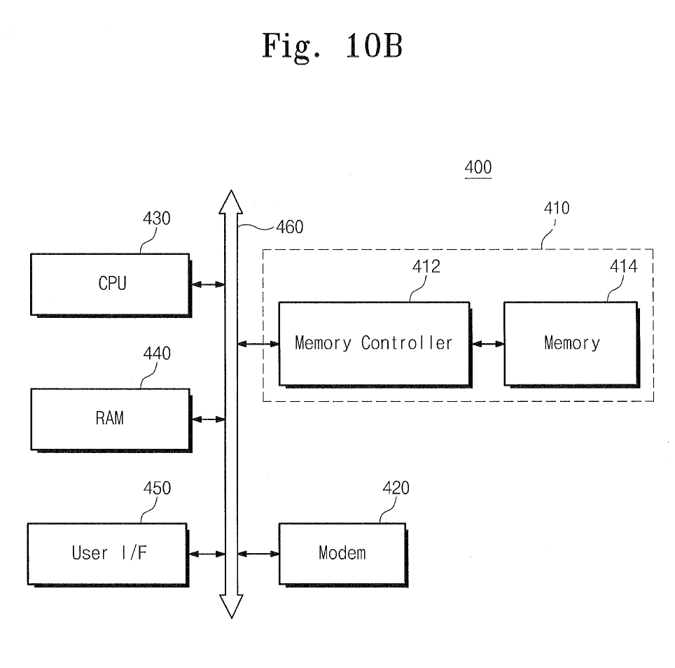

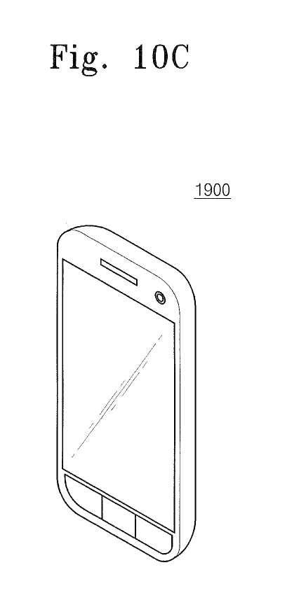

FIG. 10A is a block diagram illustrating a memory card including a semiconductor module in accordance with embodiments of the inventive concept.

Referring to FIG. 10A, a semiconductor module in accordance with embodiments of the inventive concept is applied to a memory card 300. According to an embodiment, the memory card 300 includes a memory controller 320 controlling all the data exchange between a host and a memory 310 (e.g., a resistance memory). A SRAM 322 is used as an operation memory of a central processing unit 324. A host interface 326 includes a data exchange protocol of the host accessed to the memory card. An error correction code 328 detects and corrects errors included in data read out from the memory 310. A memory interface 330 interfaces with the memory 310. The central processing unit 324 performs all the control operations for a data exchange of the memory controller 320.

The semiconductor memory 310 applied to the memory card 300 is a semiconductor module of the embodiments of the inventive concept, improving adhesive strength between molding portions. Also, the adhesion portion includes a conductive material and is connected to a circuit to which a ground voltage of the module substrate is applied, to improve electrical reliability of the semiconductor memory 310.

FIG. 10B is a block diagram illustrating an information processing system to which a memory device in accordance with embodiments of the inventive concept is applied.

Referring to FIG. 10B, an information processing system 400 includes may include a memory system 410 including a semiconductor module in accordance with embodiments of the inventive concept. The information processing system 400 may include, for example, a mobile device or a computer. According to an embodiment, the information processing system 400 includes the memory system 410 and a modem 420, a central processing unit 430, a RAM 440 and a user interface 450 that are electrically connected to a system bus 460. The memory system 410 stores data processed by the central processing unit 430 and/or data received from an external source. The memory system 410 includes a memory 414 and a memory controller 412 and, in accordance with an embodiment of the inventive concept, may have the same structure as the memory card 300 of FIG. 10A. The information processing system 400 may include a memory card, a solid state disk, a camera image processor and application chipsets. As an illustration, the memory system 410 may comprise a solid state disk (SSD). The information processing system 400 may stably and reliably store large amounts of data in the memory system 410.

The embodiments of the inventive concept in accordance with FIGS. 1 through 10B may be applied to various electronic devices. FIG. 10C illustrates a cell phone to which a semiconductor module in accordance with embodiments of the inventive concept is applied. The embodiments of the inventive concept may also be applied to, for example, a game machine, a portable notebook device, a navigation device, a vehicle or home appliances.

According to embodiments of the inventive concept, an adhesion portion is disposed between first and second molding portions to improve adhesive strength between the first and second molding portions. Also, the adhesion portion including a conductive material is connected to a circuit of the module substrate to which a ground electric potential is applied and thereby electromagnetic interference (EMI) and noise characteristics may be improved. Thermal emission characteristics of a semiconductor module may be improved by an adhesion portion to which thermal interface material (TIM), metal paste and/or nano-particles are added.

Although embodiments of the present inventive concept have been shown and described, it will be appreciated by those skilled in the art that changes may be made without departing from the principles and spirit of the inventive concept, the scope of which is defined in the appended claims.

1. A semiconductor package comprising:
a circuit substrate;
a semiconductor chip mounted on the circuit substrate;
a chip package interaction disposed between the circuit substrate and the semiconductor chip;
a first molding portion covering part of the semiconductor chip and part of the chip package interaction;
a second molding portion formed on the first molding portion; and
an adhesion portion disposed between the first and second molding portions, and adhering the first and second molding portions to each other.

2. The semiconductor package of claim 1, wherein:
the semiconductor chip includes a first side facing the chip package interaction and a second side opposite the first side, and
a top surface of the first molding portion is even with the second side of the semiconductor chip.

3. The semiconductor package of claim 1, wherein the adhesion portion includes:
a first part disposed on a top side of the semiconductor chip;
a second part extending along a side surface of the semiconductor chip perpendicular to the top side, the second part extending from opposite ends of the first part; and
a third part extending onto the circuit substrate from two different ends of the second part.

4. The semiconductor package of claim 3, wherein the first, second and third parts have a same thickness.

5. The semiconductor package of claim 3, wherein the first part and the third part have a first thickness and the second part has a second thickness smaller than the first thickness.

6. The semiconductor package of claim 3, wherein the first, second and third parts have a first thickness and a portion where the first part meets the second part has a second thickness greater than the first thickness.

7. The semiconductor package of claim 1, wherein:
the semiconductor chip includes a first side facing the chip package interaction and a second side opposite the first side, and
the first molding portion covers the first side of the semiconductor chip/

8. The semiconductor package of claim 7, wherein the adhesion portion includes:
a first part disposed on a top surface of the first molding portion;
a second part extending along sides perpendicular to the top surface of the first molding portion from opposite ends of the first part; and
a third part extending onto the circuit substrate from two different ends of the second part.

9. The semiconductor package of claim 1, wherein the second molding portion surrounds sides of the semiconductor package perpendicular to a top surface of the first molding portion,
and wherein a top surface of the second molding portion is even with the top surface of the first molding portion or extends higher than the top surface of the first molding portion by a thickness of the adhesion portion.

10. The semiconductor package of claim 1, wherein the adhesion portion comprises epoxy resin, polyimide or permanent photoresist.

11. The semiconductor package of claim 10, wherein the adhesion portion further comprises at least one selected from a group consisting of thermal interface material, metal paste, nano-particles, metal foil and shielding case material.

12. A semiconductor package comprising:
a substrate;
a semiconductor chip mounted on the substrate;
a molding structure covering the semiconductor chip and the substrate,
wherein the molding structure comprises:
a first part adjacent to the semiconductor chip;
a second part surrounding the first part; and
an adhesion portion disposed between the first part and the second part.

13. The semiconductor package of claim 12, further comprising a circuit substrate, wherein the substrate and the semiconductor chip are sequentially stacked on the circuit substrate,
wherein the first part of the molding structure covers a side of the semiconductor chip and extends onto the substrate,
and wherein the second part of the molding structure is disposed covers the first part of the molding structure on the side of the semiconductor chip, a side of the substrate and extends to the circuit substrate.

14.-17. (canceled)

18. A semiconductor package, comprising:
a circuit substrate;
a chip package interaction on the circuit substrate;
a plurality of semiconductor chips on the chip package interaction;
a first molding portion on lateral sides of the semiconductor chips;
an adhesion portion on the first molding portion and extending along lateral sides of the chip package interaction to the circuit substrate, and onto a top surface of the circuit substrate; and
a second molding portion on the adhesion portion extending along lateral sides of the chip package interaction to the circuit substrate.

19. The semiconductor package of claim 18, wherein the adhesion portion further extends on top of the semiconductor chips.

20. The semiconductor package of claim 18, wherein the plurality of semiconductor are positioned next to each other in a horizontal direction or vertically stacked on the chip package interaction.
